(19) United States
(12) Patent Application Publication
(10) Pub. No.: US 2023/0085766 A1
(43) Pub. Date: Mar. 23, 2023

(54) SUBSTRATE, METHOD OF MANUFACTURING SAME, AND DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventor: Hongbo Hu, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/960,535

(22) PCT Filed: Jun. 18, 2020
(86) PCT No.: PCT/CN2020/096815

§ 371 Date: Jul. 7, 2020

(30) Foreign Application Priority Data
Jun. 9, 2020 (CN) 202010519240.8

(51) Int. Cl. H10K 59/131; H10K 71/00; H10K 50/844

(52) U.S. Cl. CPC H01L 27/3276; H01L 51/56; H01L 51/5253; H01L 2227/323

(57) ABSTRACT

A substrate, a method of manufacturing the same, and a display panel are provided. The substrate includes a base; a first conductive layer formed on the base and patterned to form a first metal line, wherein the first conductive layer has a multi-film layer structure composed of a first metal and a second metal, and the second metal is close to the base and is easily etched; an insulating layer; a second conductive layer patterned to form a second metal line and a first metal protection line, wherein the first metal protection line covers a side of the first metal line not covered by the insulating layer.

### FIELD OF INVENTION

The present application relates to the field of display technologies, and more particularly to a substrate, a method of manufacturing the same, and a display panel.

### BACKGROUND OF INVENTION

In the manufacturing process of display panels, metal etching processes (wet etching or dry etching) are often used to form metal patterns and functionalizations. On the same substrate, it generally includes at least two metal film layers. The two adjacent metal film layers are separated by an insulating layer to prevent short circuit of a circuit. At the same time, a front metal is protected from the etching process of a back metal.

In a design of a display panel, a side of the front metal is usually protected by an insulating layer. Due to functional complexity of a circuit and a protective layer of the display panel, there will be exposed side metal without protection of the insulating layer, such as chip bonding terminals, metal wirings in a package area of a flexible active-matrix organic light emitting diode (AMOLED), etc. There is a certain risk of corrosion of exposed side front metal in the etching process of a back metal. In particular, a front metal film layer has a two-layer or three-layer metal film layer structure. Although stability of a surface metal is higher and the etching rate is slower, an underlying or intermediate metal is easily corroded during the wet etching process.

Therefore, during the etching of the back metal, the exposed side front metal is prone to side corrosion, which will reduce reliability of a product, and may even cause a film layer to peel off, resulting in product failure.

### SUMMARY OF INVENTION

The present application provides a substrate, a method of manufacturing the same, and a display panel, to improve an issue of side corrosion of a front metal during an etching process of a back metal in the prior art.

An embodiment of the present application provides a substrate comprising a base; a first conductive layer formed on the base and patterned to form a first metal line, wherein the first conductive layer has a multi-film layer structure composed of a first metal and a second metal, a surface of the first conductive layer away from the base is a first metal film layer; the first metal is a metal that is not easily etched, and the second metal is a metal that is easily etched; an insulating layer formed on the first conductive layer; a second conductive layer formed on the insulating layer and patterned to form a second metal line and a first metal protection line, wherein the first metal protection line covers a side of the first metal line not covered by the insulating layer.

In the substrate provided by an embodiment of the present application, the first conductive layer has a double film layer structure composed of metal titanium/metal aluminum, metal titanium/metal copper, or metal molybdenum/metal aluminum, metal titanium or metal molybdenum is the first metal, and metal aluminum or metal copper is the second metal.

In the substrate provided by an embodiment of the present application, the first conductive layer has a triple film layer structure composed of metal titanium/metal aluminum/metal titanium, metal titanium/metal copper/metal titanium, or metal molybdenum/metal aluminum/metal molybdenum, metal titanium or metal molybdenum is the first metal, and metal aluminum or metal copper is the second metal.

In the substrate provided by an embodiment of the present application, the second conductive layer has a single film layer structure.

In the substrate provided by an embodiment of the present application, material of the second conductive layer comprises metal copper or metal aluminum.

In the substrate provided by an embodiment of the present application, the second conductive layer has a multi-film layer structure.

In the substrate provided by an embodiment of the present application, the second conductive layer has a double film layer structure.

In the substrate provided by an embodiment of the present application, the second conductive layer has a double film layer structure composed of metal titanium/metal aluminum, metal titanium/metal copper, or metal molybdenum/metal aluminum.

In the substrate provided by an embodiment of the present application, the second conductive layer has a triple film layer structure.

In the substrate provided by an embodiment of the present application, the second conductive layer has a triple film layer structure composed of metal titanium/metal aluminum/metal titanium, metal titanium/metal copper/metal titanium, or metal molybdenum/metal aluminum/metal molybdenum.

An embodiment of the present application further provides a method of manufacturing a substrate comprising providing a base; forming a first conductive layer film on the base, patterning the first conductive layer film to obtain a first conductive layer; wherein the first conductive layer has a multi-film layer structure composed of a first metal and a second metal, a surface of the first conductive layer away from the base is a first metal film layer; the first metal is a metal that is not easily etched, the second metal is a metal that is easily etched, and the first conductive layer comprises a first metal line; depositing an insulating layer on the first conductive layer; forming a second conductive layer film on the insulating layer; depositing a photoresist layer film on the second conductive layer film; patterning the photoresist layer film to obtain a photoresist layer; using the photoresist layer as a self-aligned mask to etch the second conductive layer film; removing the photoresist layer to obtain a second conductive layer, wherein the second conductive layer comprises a second metal line and a first metal protection line, wherein the first metal protection line covers a side of the first metal line not covered by the insulating layer.

In addition, an embodiment of the present application further provides a display panel comprising a substrate, and the substrate comprises a base; a first conductive layer formed on the base and patterned to form a first metal line, wherein the first conductive layer has a multi-film layer structure composed of a first metal and a second metal, a surface of the first conductive layer away from the base is a first metal film layer; the first metal is a metal that is not easily etched, and the second metal is a metal that is easily etched; an insulating layer formed on the first conductive layer; a second conductive layer formed on the insulating layer and patterned to form a second metal line and a first metal protection line, wherein the first metal protection line covers a side of the first metal line not covered by the insulating layer.

In the display panel provided by an embodiment of the present application, the first conductive layer has a double film layer structure composed of metal titanium/metal aluminum, metal titanium/metal copper, or metal molybdenum/metal aluminum, metal titanium or metal molybdenum is the first metal, and metal aluminum or metal copper is the second metal.

In the display panel provided by an embodiment of the present application, the first conductive layer has a triple film layer structure composed of metal titanium/metal aluminum/metal titanium, metal titanium/metal copper/metal titanium, or metal molybdenum/metal aluminum/metal molybdenum, metal titanium or metal molybdenum is the first metal, and metal aluminum or metal copper is the second metal.

In the display panel provided by an embodiment of the present application, the second conductive layer has a single film layer structure.

In the display panel provided by an embodiment of the present application, material of the second conductive layer comprises metal copper or metal aluminum.

In the display panel provided by an embodiment of the present application, the second conductive layer has a multi-film layer structure.

In the display panel provided by an embodiment of the present application, the second conductive layer has a double film layer structure.

In the display panel provided by an embodiment of the present application, the second conductive layer has a double film layer structure composed of metal titanium/metal aluminum, metal titanium/metal copper, or metal molybdenum/metal aluminum.

In the display panel provided by an embodiment of the present application, the second conductive layer has a triple film layer structure composed of metal titanium/metal aluminum/metal titanium, metal titanium/metal copper/metal titanium, or metal molybdenum/metal aluminum/metal molybdenum.

### Beneficial Effect

An embodiment of the present application provides a substrate, a method of manufacturing the same, and a display panel. The substrate comprises a base; a first conductive layer formed on the base and patterned to form a first metal line, wherein the first conductive layer has a multi-film layer structure composed of a first metal and a second metal, a surface of the first conductive layer away from the base is a first metal film layer; the first metal is a metal that is not easily etched, and the second metal is a metal that is easily etched; an insulating layer formed on the first conductive layer; a second conductive layer formed on the insulating layer and patterned to form a second metal line and a first metal protection line, wherein the first metal protection line covers a side of the first metal line not covered by the insulating layer. By arranging the first metal protection line on the side of the first metal line that is not covered by the insulating layer, on the premise of not changing a circuit structure of the substrate and increasing the manufacturing process, during the etching process of the second conductive layer, the photoresist above the first metal protection line is used to protect the side of the first metal line not covered by the insulating layer. This avoids side etching of the first metal line during the etching process of the second conductive layer and improves product reliability and manufacturing yield.

### DESCRIPTION OF DRAWINGS

The technical solutions and other beneficial effects of the present application will be apparent through the detailed description of the specific implementation of the present application in conjunction with the accompanying drawings.

FIG. 1 is a first schematic cross-sectional view of a substrate provided by an embodiment of the present application.

FIG. 2 is a second schematic plan view of a substrate provided by an embodiment of the present application.

FIG. 3 is a first schematic plan view of a substrate provided by an embodiment of the present application.

FIG. 4 is a second schematic plan view of a substrate provided by an embodiment of the present application.

FIG. 5 is a flowchart of a method of manufacturing a substrate provided by an embodiment of the present application.

### DETAILED DESCRIPTION OF PREFERRED EMBODIMENTS

Aiming at an issue of side corrosion of a front metal during an etching process of a back metal in the prior art, the present application provides a substrate to alleviate this issue.

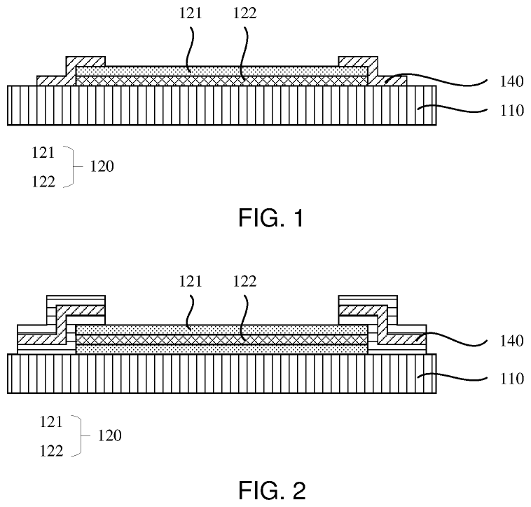

As shown in FIG. 1 to FIG. 4, a substrate provided by embodiments of the present application includes a base 110; a first conductive layer formed on the base 110 and patterned to form a first metal line 120, wherein the first conductive layer has a multi-film layer structure composed of a first metal and a second metal, a surface of the first conductive layer away from the base 110 is a first metal film layer; the first metal is a metal that is not easily etched, and the second metal is a metal that is easily etched; an insulating layer 130 formed on the first conductive layer; a second conductive layer formed on the insulating layer 130 and patterned to form a second metal line (not shown) and a first metal protection line 140, wherein the first metal protection line 140 covers a side of the first metal line 120 not covered by the insulating layer 130.

An embodiment of the present application provides a substrate. The substrate comprises a base; a first conductive layer formed on the base and patterned to form a first metal line, wherein the first conductive layer has a multi-film layer structure composed of a first metal and a second metal, a surface of the first conductive layer away from the base is a first metal film layer; the first metal is a metal that is not easily etched, and the second metal is a metal that is easily etched; an insulating layer formed on the first conductive layer; a second conductive layer formed on the insulating layer and patterned to form a second metal line and a first metal protection line, wherein the first metal protection line covers a side of the first metal line not covered by the insulating layer. By arranging the first metal protection line on the side of the first metal line that is not covered by the insulating layer, on the premise of not changing a circuit structure of the substrate and increasing the manufacturing process, during the etching process of the second conductive layer, the photoresist above the first metal protection line is used to protect the side of the first metal line not covered by the insulating layer. This avoids side etching of the first metal line during the etching process of the second conductive layer and improves product reliability and manufacturing yield.

In an embodiment of the present application, the first conductive layer has a double film layer structure composed of the first metal 121/the second metal 122, as illustrated in FIG. 1. A stacked structure of the first metal 121/second metal 122 may be a stacked structure of metal titanium/metal aluminum, wherein the metal titanium is the first metal 121 and the metal aluminum is the second metal 122. The stacked structure of the first metal 121/the second metal 122 may also be a stacked structure of the metal titanium/metal copper, wherein the metal titanium is the first metal 121 and the metal copper is the second metal 122. The stacked structure of the first metal 121/the second metal 122 may also be a stacked structure of metal molybdenum/metal aluminum, where the metal molybdenum is the first metal 121 and the metal aluminum is the second metal 122; or other double film layer structure in which the first metal 121 is a metal that is not easily etched and the second metal 122 is a metal that is easily etched.

In one embodiment, the second conductive layer has a single film layer structure, as illustrated in FIG. 1. The second conductive layer may be a single film layer structure of metal copper or a single film layer structure of metal aluminum.

In another embodiment, the second conductive layer has a double film layer structure. The second conductive layer may be a double film layer structure composed of metal titanium/metal aluminum. The second conductive layer may also be a double film layer structure composed of metal titanium/metal copper. The second conductive layer may also be a double film layer structure composed of metal molybdenum/metal aluminum, or a double film layer structure composed of other metals.

In yet another embodiment, the second conductive layer has a triple film layer structure, as illustrated in FIG. 2. The second conductive layer may be a triple film layer structure of metal titanium/metal copper/metal titanium. The second conductive layer may also be a triple film layer structure composed of metal titanium/metal aluminum/metal titanium. The second conductive layer may also be a triple film layer structure composed of metal molybdenum/metal aluminum/metal molybdenum, or a triple film layer structure composed of other metals.

In an embodiment, the first conductive layer is a double film layer structure composed of a first metal/a second metal, wherein the first metal is a metal that is not easily etched, and the second metal is a metal that is easily etched. By arranging the first metal protection line on the side of the first metal line that is not covered by the insulating layer, during the etching process of the second conductive layer, the photoresist above the first metal protection line is used to protect the side of the first metal line not covered by the insulating layer. This avoids side etching of the first metal line during the etching process of the second conductive layer, protects the first metal line, and improves product reliability and manufacturing yield.

In another embodiment, the first conductive layer is a tripe film layer structure composed of a first metal 121/second metal 122/first metal 121, as illustrated in FIG. 2. A stacked structure of the first metal 121/second metal 122/first metal 121 may be a stacked structure of metal titanium/metal aluminum/metal titanium, wherein the metal titanium is the first metal 121 and the metal aluminum is the second metal 122. The stacked structure of the first metal 121/the second metal 122/the first metal 121 can also be a stacked structure of the metal titanium/metal copper/metal titanium, wherein the metal titanium is the first metal 121 and the metal copper is the second metal 122. The stacked structure of the first metal 121/second metal 122/first metal 121 may also be a stacked structure of metal molybdenum/metal aluminum/metal molybdenum, wherein the metal molybdenum is the first metal 121 and the metal aluminum is the second metal 122; or other tripe film layer structure in which the first metal 121 is a metal that is not easily etched and the second metal 122 is a metal that is easily etched.

In one embodiment, the second conductive layer has a single film layer structure, as illustrated in FIG. 1. The second conductive layer may be a single film layer structure of metal copper or a single film layer structure of metal aluminum.

In another embodiment, the second conductive layer has a double film layer structure. The second conductive layer may be a double film layer structure composed of metal titanium/metal aluminum. The second conductive layer may also be a double film layer structure composed of metal titanium/metal copper. The second conductive layer may also be a double film layer structure composed of metal molybdenum/metal aluminum, or a double film layer structure composed of other metals.

In yet another embodiment, the second conductive layer has a triple film layer structure, as illustrated in FIG. 2. The second conductive layer may be a triple film layer structure of metal titanium/metal copper/metal titanium. The second conductive layer may also be a triple film layer structure composed of metal titanium/metal aluminum/metal titanium. The second conductive layer may also be a triple film layer structure composed of metal molybdenum/metal aluminum/metal molybdenum, or a triple film layer structure composed of other metals.

In an embodiment, the first conductive layer is a triple film layer structure composed of a first metal/second metal/first metal, wherein the first metal is a metal that is not easily etched, and the second metal is a metal that is easily etched. By arranging the first metal protection line on the side of the first metal line that is not covered by the insulating layer, during the etching process of the second conductive layer, the photoresist above the first metal protection line is used to protect the side of the first metal line not covered by the insulating layer. This avoids corrosion of the second metal in the first metal line by the etching process of the second conductive layer, protects the first metal line, and improves product reliability and manufacturing yield.

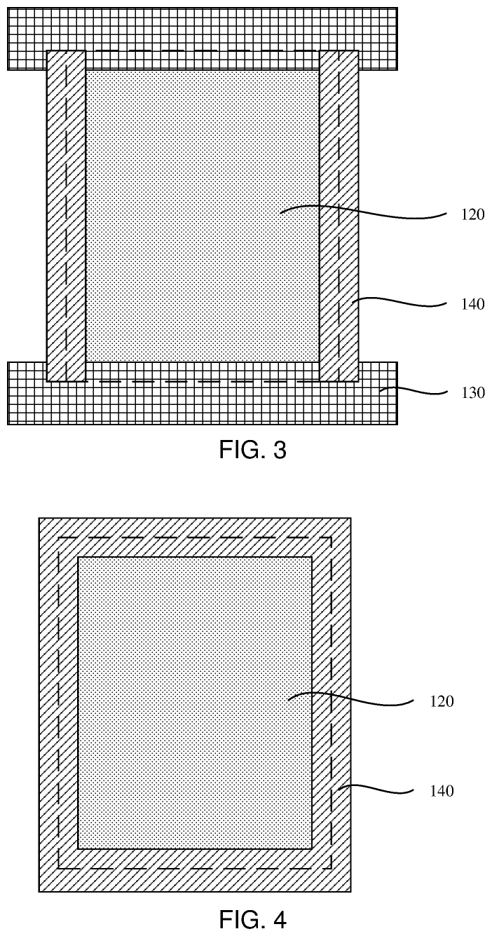

In one embodiment, at least one side of the first metal line 120 is covered by an insulating layer. For example, the first metal line 120 is a metal trace in a package area of a flexible AMOLED. The insulating layer above some areas of these metal traces will be removed during the manufacturing process. As a result, at least one side of the metal trace is exposed, and the exposed side has a risk of side corrosion during the etching process of the back metal film layer. Referring to FIG. 3, the upper and lower sides of the first metal line 120 are covered by the insulating layer 130. The left and right sides of the first metal line 120 are not covered by the insulating layer 130. The left and right sides of the first metal line 120 are covered by the first metal protection line 140.

In an embodiment, by arranging the first metal protection line on the side of the first metal line that is not covered by the insulating layer, during the etching process of the second conductive layer, the photoresist above the first metal protection line is used to protect the side of the first metal line not covered by the insulating layer. This avoids side etching of the first metal line during the etching process of the second conductive layer, protects the first metal line, and improves product reliability and manufacturing yield.

In another embodiment, the sides of the first metal line 120 are not covered by the insulating layer. For example, the first metal line 120 is a chip bonding terminal. Since the insulating layer above the chip bonding terminal is completely removed during the second comparison, the four sides of the chip bonding terminal are all exposed, and the exposed sides have the risk of side erosion during the etching of the back metal film layer. Referring to FIG. 4, the four sides of the first metal line 120 are covered by the first metal protection line 140.

In an embodiment, by arranging the first metal protection line on the four sides of the first metal line that are not covered by the insulating layer, during the etching process of the second conductive layer, the photoresist above the first metal protection line is used to protect the side of the first metal line not covered by the insulating layer. This avoids side etching of the first metal line during the etching process of the second conductive layer and improves product reliability and manufacturing yield.

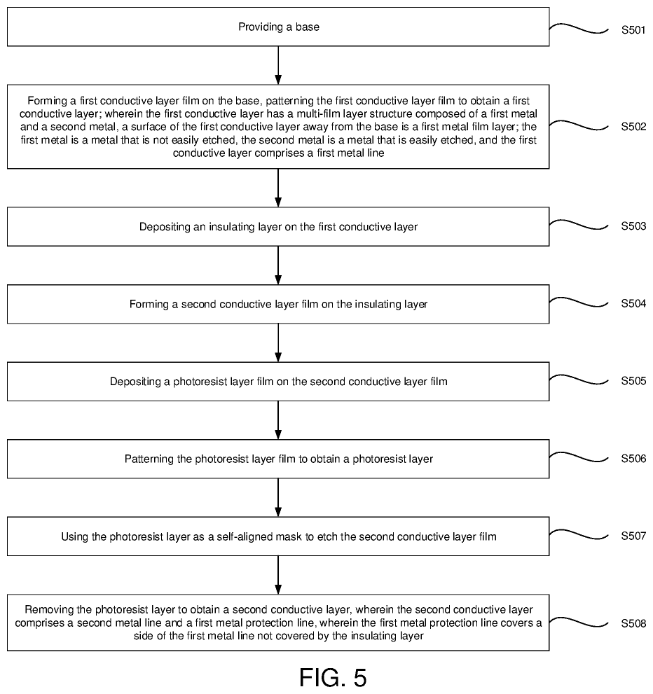

An embodiment of the present application further provides a method of manufacturing a substrate. Referring to FIG. 5, the manufacturing method comprises:

Step S501, providing a base.

Step S502, forming a first conductive layer film on the base, patterning the first conductive layer film to obtain a first conductive layer; wherein the first conductive layer has a multi-film layer structure composed of a first metal and a second metal, a surface of the first conductive layer away from the base is a first metal film layer; the first metal is a metal that is not easily etched, the second metal is a metal that is easily etched, and the first conductive layer comprises a first metal line.

Step S503, depositing an insulating layer on the first conductive layer.

Step S504, forming a second conductive layer film on the insulating layer.

Step S505, depositing a photoresist layer film on the second conductive layer film.

Step S506, patterning the photoresist layer film to obtain a photoresist layer.

Step S507, using the photoresist layer as a self-aligned mask to etch the second conductive layer film.

Step S508, removing the photoresist layer to obtain a second conductive layer, wherein the second conductive layer comprises a second metal line and a first metal protection line, wherein the first metal protection line covers a side of the first metal line not covered by the insulating layer.

An embodiment of the present application provides a method of manufacturing a substrate comprising providing a base; forming a first conductive layer film on the base, patterning the first conductive layer film to obtain a first conductive layer; wherein the first conductive layer has a multi-film layer structure composed of a first metal and a second metal, a surface of the first conductive layer away from the base is a first metal film layer; the first metal is a metal that is not easily etched, the second metal is a metal that is easily etched, and the first conductive layer comprises a first metal line; depositing an insulating layer on the first conductive layer; forming a second conductive layer film on the insulating layer; depositing a photoresist layer film on the second conductive layer film; patterning the photoresist layer film to obtain a photoresist layer; using the photoresist layer as a self-aligned mask to etch the second conductive layer film; removing the photoresist layer to obtain a second conductive layer, wherein the second conductive layer comprises a second metal line and a first metal protection line, wherein the first metal protection line covers a side of the first metal line not covered by the insulating layer. By arranging the first metal protection line on the side of the first metal line that is not covered by the insulating layer, on the premise of not changing a circuit structure of the substrate and increasing the manufacturing process, during the etching process of the second conductive layer, the photoresist above the first metal protection line is used to protect the side of the first metal line not covered by the insulating layer. This avoids side etching of the first metal line during the etching process of the second conductive layer and improves product reliability and manufacturing yield.

An embodiment of the present application also provides a display panel. The display panel includes any substrate provided in an embodiment of the present application. The substrate includes a base; a first conductive layer formed on the base and patterned to form a first metal line, wherein the first conductive layer has a multi-film layer structure composed of a first metal and a second metal, a surface of the first conductive layer away from the base is a first metal film layer; the first metal is a metal that is not easily etched, and the second metal is a metal that is easily etched; an insulating layer formed on the first conductive layer; a second conductive layer formed on the insulating layer and patterned to form a second metal line and a first metal protection line, wherein the first metal protection line covers a side of the first metal line not covered by the insulating layer.

An embodiment of the present application provides a display comprising a substrate. The substrate comprises a base; a first conductive layer formed on the base and patterned to form a first metal line, wherein the first conductive layer has a multi-film layer structure composed of a first metal and a second metal, a surface of the first conductive layer away from the base is a first metal film layer; the first metal is a metal that is not easily etched, and the second metal is a metal that is easily etched; an insulating layer formed on the first conductive layer; a second conductive layer formed on the insulating layer and patterned to form a second metal line and a first metal protection line, wherein the first metal protection line covers a side of the first metal line not covered by the insulating layer. By arranging the first metal protection line on the side of the first metal line that is not covered by the insulating layer, on the premise of not changing a circuit structure of the substrate and increasing the manufacturing process, during the etching process of the second conductive layer, the photoresist above the first metal protection line is used to protect the side of the first metal line not covered by the insulating layer. This avoids side etching of the first metal line during the etching process of the second conductive layer and improves product reliability and manufacturing yield.

In an embodiment of the present application, the first conductive layer has a double film layer structure.

In an embodiment of the present application, the first conductive layer has a double film layer structure composed of metal titanium/metal aluminum, metal titanium/metal copper, or metal molybdenum/metal aluminum, metal titanium or metal molybdenum is the first metal, and metal aluminum or metal copper is the second metal.

In an embodiment of the present application, the first conductive layer has a triple film layer structure.

In an embodiment of the present application, the first conductive layer has a triple film layer structure composed of metal titanium/metal aluminum/metal titanium, metal titanium/metal copper/metal titanium, or metal molybdenum/metal aluminum/metal molybdenum, metal titanium or metal molybdenum is the first metal, and metal aluminum or metal copper is the second metal.

In an embodiment of the present application, the second conductive layer has a single film layer structure.

In an embodiment of the present application, material of the second conductive layer comprises metal copper or metal aluminum.

In an embodiment of the present application, the second conductive layer has a multi-film layer structure.

In an embodiment of the present application, the second conductive layer has a double film layer structure composed of metal titanium/metal aluminum, metal titanium/metal copper, or metal molybdenum/metal aluminum.

In an embodiment of the present application, the second conductive layer has a triple film layer structure composed of metal titanium/metal aluminum/metal titanium, metal titanium/metal copper/metal titanium, or metal molybdenum/metal aluminum/metal molybdenum.

According to the above embodiment, an embodiment of the present application provides a substrate, a method of manufacturing the same, and a display panel. The substrate comprises a base; a first conductive layer formed on the base and patterned to form a first metal line, wherein the first conductive layer has a multi-film layer structure composed of a first metal and a second metal, a surface of the first conductive layer away from the base is a first metal film layer; the first metal is a metal that is not easily etched, and the second metal is a metal that is easily etched; an insulating layer formed on the first conductive layer; a second conductive layer formed on the insulating layer and patterned to form a second metal line and a first metal protection line, wherein the first metal protection line covers a side of the first metal line not covered by the insulating layer. By arranging the first metal protection line on the side of the first metal line that is not covered by the insulating layer, on the premise of not changing a circuit structure of the substrate and increasing the manufacturing process, during the etching process of the second conductive layer, the photoresist above the first metal protection line is used to protect the side of the first metal line not covered by the insulating layer. This avoids side etching of the first metal line during the etching process of the second conductive layer and improves product reliability and manufacturing yield.

In summary, although the present application has been disclosed as above with preferred embodiments, the above preferred embodiments are not intended to limit the present application. Those of ordinary skill in the art can make various changes and modifications without departing from the spirit and scope of the present application. Therefore, the protection scope of the present application is subject to the scope defined by the claims.

What is claimed is:

1. A substrate, comprising:
a base;
a first conductive layer formed on the base and patterned to form a first metal line, wherein the first conductive layer has a multi-film layer structure composed of a first metal and a second metal, a surface of the first conductive layer away from the base is a first metal film layer; the first metal is a metal that is not easily etched, and the second metal is a metal that is easily etched;
an insulating layer formed on the first conductive layer;
a second conductive layer formed on the insulating layer and patterned to form a second metal line and a first metal protection line, wherein the first metal protection line covers a side of the first metal line not covered by the insulating layer.

2. The substrate according to claim 1, wherein the first conductive layer has a double film layer structure composed of metal titanium/metal aluminum, metal titanium/metal copper, or metal molybdenum/metal aluminum, metal titanium or metal molybdenum is the first metal, and metal aluminum or metal copper is the second metal.

3. The substrate according to claim 1, wherein the first conductive layer has a triple film layer structure composed of metal titanium/metal aluminum/metal titanium, metal titanium/metal copper/metal titanium, or metal molybdenum/metal aluminum/metal molybdenum, metal titanium or metal molybdenum is the first metal, and metal aluminum or metal copper is the second metal.

4. The substrate according to claim 1, wherein the second conductive layer has a single film layer structure.

5. The substrate according to claim 4, wherein material of the second conductive layer comprises metal copper or metal aluminum.

6. The substrate according to claim 1, wherein the second conductive layer has a multi-film layer structure.

7. The substrate according to claim 6, wherein the second conductive layer has a double film layer structure.

8. The substrate according to claim 7, wherein the second conductive layer has a double film layer structure composed of metal titanium/metal aluminum, metal titanium/metal copper, or metal molybdenum/metal aluminum.

9. The substrate according to claim 6, wherein the second conductive layer has a triple film layer structure.

10. The substrate according to claim 9, wherein the second conductive layer has a triple film layer structure composed of metal titanium/metal aluminum/metal titanium, metal titanium/metal copper/metal titanium, or metal molybdenum/metal aluminum/metal molybdenum.

11. A method of manufacturing a substrate, comprising:
providing a base;
forming a first conductive layer film on the base, patterning the first conductive layer film to obtain a first conductive layer; wherein the first conductive layer has a multi-film layer structure composed of a first metal and a second metal, a surface of the first conductive layer away from the base is a first metal film layer; the first metal is a metal that is not easily etched, the second metal is a metal that is easily etched, and the first conductive layer comprises a first metal line;
depositing an insulating layer on the first conductive layer;
forming a second conductive layer film on the insulating layer;
depositing a photoresist layer film on the second conductive layer film;
patterning the photoresist layer film to obtain a photoresist layer;
using the photoresist layer as a self-aligned mask to etch the second conductive layer film;
removing the photoresist layer to obtain a second conductive layer, wherein the second conductive layer comprises a second metal line and a first metal protection line, wherein the first metal protection line covers a side of the first metal line not covered by the insulating layer.

12. A display panel comprising a substrate, and the substrate comprising:
a base;
a first conductive layer formed on the base and patterned to form a first metal line, wherein the first conductive layer has a multi-film layer structure composed of a first metal and a second metal, a surface of the first conductive layer away from the base is a first metal film layer; the first metal is a metal that is not easily etched, and the second metal is a metal that is easily etched;
an insulating layer formed on the first conductive layer;
a second conductive layer formed on the insulating layer and patterned to form a second metal line and a first metal protection line, wherein the first metal protection line covers a side of the first metal line not covered by the insulating layer.

13. The display panel according to claim 12, wherein the first conductive layer has a double film layer structure composed of metal titanium/metal aluminum, metal titanium/metal copper, or metal molybdenum/metal aluminum, metal titanium or metal molybdenum is the first metal, and metal aluminum or metal copper is the second metal.

14. The display panel according to claim 12, wherein the first conductive layer has a triple film layer structure composed of metal titanium/metal aluminum/metal titanium, metal titanium/metal copper/metal titanium, or metal molybdenum/metal aluminum/metal molybdenum, metal titanium or metal molybdenum is the first metal, and metal aluminum or metal copper is the second metal.

15. The display panel according to claim 12, wherein the second conductive layer has a single film layer structure.

16. The display panel according to claim 15, wherein material of the second conductive layer comprises metal copper or metal aluminum.

17. The display panel according to claim 12, wherein the second conductive layer has a multi-film layer structure.

18. The display panel according to claim 17, wherein the second conductive layer has a double film layer structure.

19. The display panel according to claim 18, wherein the second conductive layer has a double film layer structure composed of metal titanium/metal aluminum, metal titanium/metal copper, or metal molybdenum/metal aluminum.

20. The display panel according to claim 17, wherein the second conductive layer has a triple film layer structure composed of metal titanium/metal aluminum/metal titanium, metal titanium/metal copper/metal titanium, or metal molybdenum/metal aluminum/metal molybdenum.
